(19) United States
(12) Patent Application Publication
(10) Pub. No.: US 2013/0289909 A1
(43) Pub. Date: Oct. 31, 2013

(54) ELECTRONIC DEVICE AND METHOD FOR MONITORING PARAMETER VALUES OF THE ELECTRONIC DEVICE

(71) Applicant: HON HAI PRECISION INDUSTRY CO., LTD., New Taipei (TW)

(72) Inventor: CHIEN-LIANG LIN, New Taipei (TW)

(73) Assignee: HON HAI PRECISION INDUSTRY CO., LTD., New Taipei (TW)

(21) Appl. No.: 13/705,186

(22) Filed: Dec. 5, 2012

(30) Foreign Application Priority Data
Apr. 27, 2012 (TW) 101115172

(51) Int. Cl. G06F 17/00; G01R 19/00; G01K 13/00

(52) U.S. Cl. CPC G06F 17/00; G01K 13/00; G01R 19/00
USPC 702/64; 702/182; 702/130

(57) ABSTRACT

A method of monitoring the working conditions and states of an electronic device sets a first time-interval to read the parameter values of the electronic device. When the electronic device is working normally, the first time-interval is replaced by a second time-interval, which is longer than the first time-interval, to reduce reading frequency, relieve the load on a baseboard management controller (BMC) of the electronic device, and save power.

### BACKGROUND

1. Technical Field

Embodiments of the present disclosure relate to parameter management technology, and more particularly to an electronic device and a method for monitoring parameter values of the electronic device.

2. Description of Related Art

A baseboard management controller (BMC) may act as a monitoring unit of an electronic device (e.g., a server or a computer), to read parameter values (e.g., temperature values and voltage values), of the electronic device according to a preset reading frequency, and to determine whether the electronic device is in a normal state. However, in many electronic devices, the preset reading frequency cannot be changed automatically when the electronic device is in a predetermined state.

For example, when the BMC reads the parameter values according to a single preset reading frequency, this increases the load on the working of the BMC, and power consumption of the electronic device remains high. Therefore, a more efficient method for monitoring the parameter values of the electronic device is desired.

### BRIEF DESCRIPTION OF THE DRAWINGS

FIG. 1 is a block diagram of one embodiment of an electronic device including a monitoring system.

FIG. 2 is a block diagram of function modules of the monitoring system included in the electronic device of FIG. 1.

FIG. 3 is a flowchart of one embodiment of a monitoring method to monitor parameter values of the electronic device of FIG. 1.

FIG. 4 is an example of reading temperature values of the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

In general, the word module, as used herein, refers to logic embodied in hardware or firmware, or to a collection of software instructions, written in a programming language, such as, Java, C, or assembly. One or more software instructions in the modules may be embedded in firmware, such as in an EPROM. The modules described herein may be implemented as either software and/or hardware modules and may be stored in any type of non-transitory computer-readable medium or other storage device. Some non-limiting examples of non-transitory computer-readable media include CDs, DVDs, BLU-RAY, flash memory, and hard disk drives.

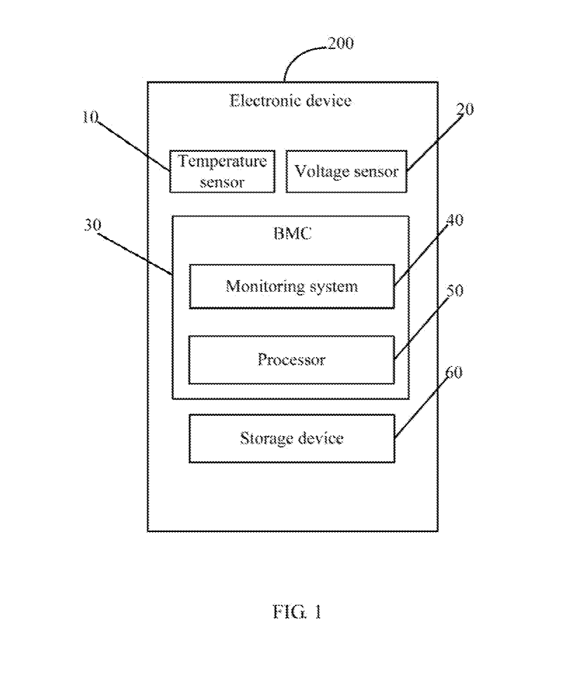

FIG. 1 is a block diagram of one embodiment of an electronic device 200 including a monitoring system 40. The electronic device 200 may be a personal computer or a server, for example. The electronic device 200 further includes a temperature sensor 10, a voltage sensor 20, and other kinds of sensors not shown in FIG. 1, a baseboard management controller (BMC) 30 which includes at least one processor 50, and a storage device 60.

The temperature sensor 10 may detect one or more temperatures of the electronic device 200, and the voltage sensor 20 may detect one or more voltages of the electronic device 200. The BMC 30 may monitor temperature values or other kinds of states or conditions (parameter values), such as fan speeds, and voltages of the electronic device 200, for example.

In one embodiment, the BMC 30 periodically reads temperature values from the temperature sensor 10 to determine whether the electronic device 200 is in a normal temperature state. In another embodiment, the BMC 30 periodically reads voltage values from the voltage sensor 20 to determine whether the electronic device 200 is in a normal voltage state.

The electronic device 200 is generally controlled and coordinated by an operating system, such as UNIX, LINUX, WINDOWS, MAC OS X, ANDROID, SYMBIAN, an embedded operating system, or any other compatible operating system. In other embodiments, the electronic device 200 may be controlled by a proprietary operating system. All such operating systems control and schedule computer processes for execution, perform memory management, provide a file system, networking, and I/O services, and provide a user interface, such as a graphical user interface (GUI), among other things.

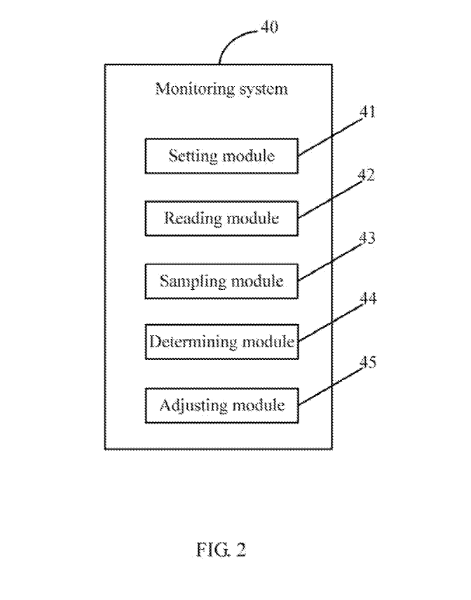

FIG. 2 is a block diagram of function modules of the monitoring system 40 included in the electronic device 200 of FIG. 1. In one embodiment, the monitoring system 40 may include a setting module 41, a reading module 42, a sampling module 43, a determining module 44, and an adjusting module 45. The modules 41-45 comprise computerized codes in the form of one or more programs that may be stored the storage device 60. The computerized code includes instructions that are executed by the at least one processor 50.

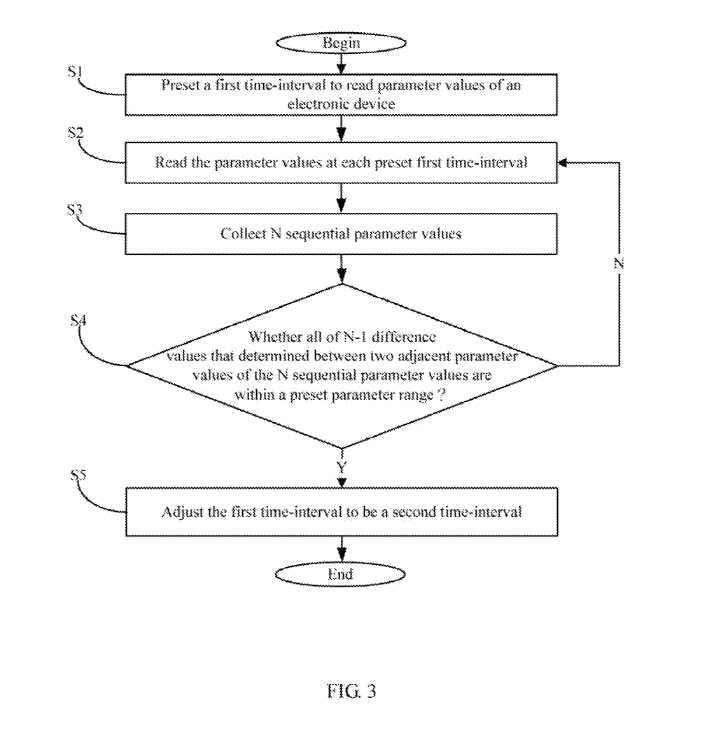

FIG. 3 is a flowchart of one embodiment of a method to monitor parameter values of the electronic device 200 of FIG. 1. Depending on the embodiment, additional steps may be added, others deleted, and the ordering of the steps may be changed.

In step S1, the setting module 41 presets a first time-interval to read parameter values of the electronic device 200. In one embodiment, the parameter values may be temperature values of the electronic device 200. In other embodiments, the parameter values may be voltage values of the electronic device 200. For example, the first time-interval of the electronic device 200 may be one second, which means the reading module 42 reads new parameter values of the electronic device every one second.

In step S2, the reading module 42 reads the parameter values of the electronic device 200 at each preset first time-interval when the electronic device 200 is initialized. The electronic device 200 being initialized means the electronic device 200 is operational after booting. In one embodiment, when the electronic device 200 is initialized, the reading module 42 reads temperature values from the temperature sensor 10 at each preset first time-interval (e.g., 1 s). In another embodiment, when the electronic device 200 is initialized, the reading module 42 reads voltage values from the voltage sensor 20 at each preset first time-interval (e.g., 1 s).

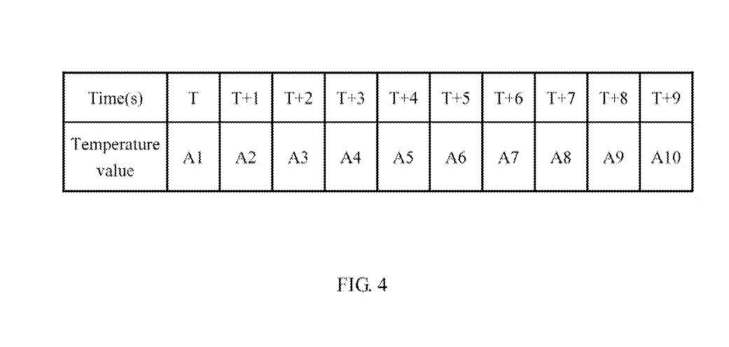

For example, as shown in FIG. 4, the reading module 42 reads a first temperature value A1 at Ts from the temperature sensor 10, reads a second temperature value A2 at (T+1)s, reads a third temperature value A3 at (T+2)s, reads a fourth temperature value A4 at (T+3)s, similarly, and reads a tenth temperature value A10 at (T+9)s.

In step S3, the sampling module 43 collects N (e.g., 10) sequential parameter values. For example, the sampling module 43 collects the ten sequential temperature values A1-A10.

In step S4, the determining module 44 determines a difference value between each two adjacent parameter values of the N sequential parameter values to acquire N−1 difference values, and determines whether all of the N−1 difference values are within a preset parameter range.

In one embodiment, when the parameter values are temperature values of the electronic device 200, the preset parameter range is determined according to a normal temperature value and a tolerance range of the temperature sensor 10. For example, if the tolerance range of the temperature sensor 10 is (−10%˜+10%), and the normal temperature value of the electronic device 200 is 30° C., the preset parameter range may be determined by multiplying the normal temperature value (30° C.) by the tolerance range (−10%˜+10%), which would be for example −3˜+3.

In another embodiment, when the parameter values are voltage values of the electronic device 200, the preset parameter range is determined according to a normal voltage value and a tolerance range of the voltage sensor 20. For example, the preset parameter range may be determined by multiplying the normal voltage value by the tolerance range of the voltage sensor 20.

The determining module 44 determines a difference value between each two adjacent parameter values of the 10 sequential temperature values first. For example, the determining module 44 subtracts A1 from A2 to acquire a first difference value B1, subtracts A2 from A3 to acquire a second difference value B2, subtracts A3 from A4 to acquire a third difference value B3, similarly, subtracts A9 from A10 to acquire a ninth difference B9. Thus, the determining module 44 can acquire 9 (N−1=10−1=9) difference values.

The determining module 44 determines whether all of the 9 difference values (i.e., B1, B2, B3, B4, B5, B6, B7, B8, B9) are within the parameter range (e.g., −3˜+3). If all of the 9 difference values are within the parameter range (e.g., −3˜+3), the determining module 44 determines that the electronic device 200 is working normally in respect of temperatures, and the process goes to step S5.

If one or more difference values of the 9 difference values are outside the parameter range (e.g., more than −3˜+3), the determining module 44 determines that the electronic device 200 is working abnormally in respect of temperatures, the process returns to step S2, that is, the reading module 42 continues to read temperature values from the temperature sensor 10 on the same schedule (e.g., once every one second).

In step S5, the adjusting module 45 adjusts the first time-interval to be a second time-interval when all of the N−1 difference values are within the preset parameter range. In one embodiment, the second time-interval is greater than the first time-interval. For example, the adjusting module 45 adjusts the second time-interval to be two seconds, then the reading module 42 reads temperature values from the temperature sensor 10 once every two seconds, that is, the reading module 42 reads parameter values at a lower and slower frequency.

Although embodiments of the present disclosure have been specifically described, the present disclosure is not to be construed as being limited thereto. Various changes or modifications may be made to the present disclosure without departing from the scope and spirit of the present disclosure.

What is claimed is:

1. An electronic device, comprising:
a storage device;
a baseboard management controller (BMC), the BMC comprising at least one processor; and
one or more programs that are stored in the storage device and are executed by the at least one processor, the one or more programs comprising:
a reading module that reads parameter values of the electronic device at a preset first time-interval;
a sampling module that collects N sequential parameter values of the electronic device;
a determining module that determines a difference value between each two adjacent parameter values of the N sequential parameter values to acquire N−1 difference values, and determines whether all of the N−1 difference values are within a preset parameter range;
an adjusting module that adjusts the first time-interval to be a second time-interval when all of the N−1 difference values are within the preset parameter range.

2. The electronic device of claim 1, wherein the reading module reads temperature values from a temperature sensor of the electronic device when the parameter values are temperature values, and the preset parameter range is determined according to a normal temperature value and a tolerance range of the temperature sensor.

3. The electronic device of claim 1, wherein the reading module reads voltage values from a voltage sensor of the electronic device when the parameter values are voltage values, and the preset parameter range is determined according to a normal voltage value and a tolerance range of the voltage sensor.

4. The electronic device of claim 1, wherein the second time-interval is greater than the first time-interval.

5. A non-transitory storage medium having stored thereon instructions that, when executed by a processor of a baseboard management controller (BMC) of an electronic device, causes the electronic device to perform a method of monitoring parameters values of the electronic device, the method comprising:
reading parameter values of the electronic device at a preset first time-interval when the electronic device is initialized;
collecting N sequential parameter values of the electronic device;
determining a difference value between each two adjacent parameter values of the N sequential parameter values to acquire N−1 difference values, and determining whether all of the N−1 difference values are within a preset parameter range;
adjusting the first time-interval to be a second time-interval when all of the N−1 difference values are within the preset parameter range.

6. The non-transitory storage medium according to claim 5, wherein reading temperature values from a temperature sensor of the electronic device when the parameter values are temperature values, and the preset parameter range is determined according to a normal temperature value and a tolerance range of the temperature sensor.

7. The non-transitory storage medium according to claim 5, wherein reading voltage values from a voltage sensor of the electronic device when the parameter values are voltage values, and the preset parameter range is determined according to a normal voltage value and a tolerance range of the voltage sensor.

8. The non-transitory storage medium according to claim 5, wherein the second time-interval is greater than the first time-interval.

9. A method of monitoring parameter values of an electronic device, the electronic device comprises a storage device, a baseboard management controller (BMC), the BMC comprises at least one processor, the method comprising:
reading parameter values of the electronic device at a preset first time-interval when the electronic device is initialized;
collecting N sequential parameter values of the electronic device;
determining a difference value between each two adjacent parameter values of the N sequential parameter values to acquire N−1 difference values, and determining whether all of the N−1 difference values are within a preset parameter range;
adjusting the first time-interval to be a second time-interval when all of the N−1 difference values are within the preset parameter range.

10. The method according to claim 9, wherein reading temperature values from a temperature sensor of the electronic device when the parameter values are temperature values, and the preset parameter range is determined according to a normal temperature value and a tolerance range of the temperature sensor.

11. The method according to claim 9, wherein reading voltage values from a voltage sensor of the electronic device when the parameter values are voltage values, and the preset parameter range is determined according to a normal voltage value and a tolerance range of the voltage sensor.

12. The method according to claim 9, wherein the second time-interval is greater than the first time-interval.
